(19) United States
(12) Patent Application Publication
(10) Pub. No.: US 2006/0170080 A1
(43) Pub. Date: Aug. 3, 2006

(54) Semiconductor device having directly attached heat spreader

(76) Inventors: Edgar R. Zuniga-Ortiz, McKinney, TX (US); Richard J. Saye, Greenville, TX (US); Lance C. Wright, Allen, TX (US)

Correspondence Address: TEXAS INSTRUMENTS INCORPORATED, P O BOX 655474, M/S 3999, DALLAS, TX, 75265, US

(21) Appl. No.: 11/050,059

(22) Filed: Feb. 3, 2005

(51) Int. Cl. H01L 23/495

(52) U.S. Cl. 257/666

(57) ABSTRACT

An apparatus consisting of a leadframe (301) and a metallic heat spreader (310). The leadframe, made of a planar metal sheet, includes a plurality of non-coplanar members (312) operable as mechanical couplers configured to grip inserted objects. The heat spreader has a central pad (310) suitable for mounting a heat-generating object, and a plurality of handles (312) in locations to match the members; the handles are coupled with the members. One member end is formed as a clamp having projections from the planar sheet, operable to grip one of the handles, when it is inserted into the coupler, and also has a bend so that the plane of the heat spreader, after insertion of its handles into the clamps, is spaced from the plane of the leadframe. A gap is thus created between the spreader and the first leadframe segment ends.

### FIELD OF THE INVENTION

The present invention is related in general to the field of electrical systems and semiconductor devices and more specifically to thermally enhanced semiconductor devices having integrated metallic chip support and heat spreader.

### DESCRIPTION OF THE RELATED ART

Removing the thermal heat generated by active components belongs to the most fundamental challenges in integrated circuit technology. Coupled with the ever shrinking component feature sizes and increasing density of device integration is an ever increasing density of power and thermal energy generation. However, in order to keep the active components at their low operating temperatures and high speed, this heat must continuously be dissipated and removed to outside heat sinks. This effort becomes increasingly harder, the higher the energy density becomes.

In known technology, one approach to heat removal, specifically for devices with metallic leads, focuses on thermal transport through the thickness of the semiconductor chip from the active surface to the passive surface. The passive surface, in turn, is attached to the chip mount pad of a metallic leadframe so that the thermal energy can flow into the chip mount pad of the metallic leadframe. The layer of the typical polymer attach material represents a thermal barrier. When properly formed, the leadframe can act as a heat spreader to an outside heat sink. In many semiconductor package designs, this implies a leadframe with a portion formed such that this portion protrudes from the plastic device encapsulation; it can thus be directly attached to the outside heat sink. In application where there is no outside heat sink available, the exposed leadframe becomes less effective when the leadframe metal thickness has to be reduced driven by the trend towards thinner packages.

Another approach of known technology, specifically for ball-grid array devices without leadframes, employs a heat spreader spaced in proximity of the active surface of the semiconductor chip, at a safe distance from the electrical connections of the active surface. In this approach, the heat has to spread first through the macroscopic thickness of the molding material (typically an epoxy filled with inorganic particles, a mediocre thermal conductor) and only then into a metallic heat spreader. Frequently, the spreader is positioned on the surface of the molded package; in other devices, it is embedded in the molded package.

The approach to add (“drop in”) a heat spreader to the assembled device is generally plagued by the need to stabilize the spreader for the molding process; otherwise, rotational and/or lateral movements may occur during the molding step.

### SUMMARY OF THE INVENTION

A need has therefore arisen for a concept of a low-cost, thermally improved and mechanically stabilized structure, which is not only robust relative to the transfer molding process, but also flexible enough to be applied to different semiconductor product families and compatible with the industry trend towards thinner device packages. The new structure should not only meet high thermal and electrical performance requirements, but should also achieve improvements towards the goals of enhanced process yields and device reliability.

The present invention provides improved thermal performance of integrated circuits, especially of the PDIP, SOIC, and SOP families. One embodiment of the invention is a leadframe made from a planar metal sheet, which has a plurality of segments operable as electrical connectors, and a plurality of non-coplanar members operable as mechanical couplers configured to grip inserted objects. The non-coplanarity of these members is provided by a bend in these members near their attachment to the leadframe.

Another embodiment of the invention is an apparatus, which consists of a leadframe, comprising a planar metal sheet, and a metallic heat spreader. The leadframe includes a plurality of segments operable as electrical connectors and a plurality of non-coplanar members operable as mechanical couplers configured to grip inserted objects. The heat spreader has a central pad suitable for mounting a heat-generating object, and a plurality of handles in locations to match the locations of the members, respectively. These handles are coupled with the members, respectively.

In the preferred embodiment, each member has first and second ends, the first end attached to the leadframe and the second end formed as a clamp having projections from the planar sheet, operable to grip one of the handles, when it is inserted into the clamp. Preferably, the second ends also have a bend so that the plane of the heat spreader, after insertion of its handles into the clamps, is spaced from the plane of the leadframe; a gap is thus created between the spreader and the first leadframe segment ends.

Another embodiment of the invention is a semiconductor device comprising a leadframe, which includes a plurality of segments having first and second ends, wherein the first ends are in a first plane. The device further comprises a metallic heat spreader in a second plane; this second plane is spaced from the first plane by a gap. The spreader has first and second surfaces, a central pad suitable for mounting a heat-generating object on the first surface, and a plurality of handles with first and second ends; the first handle ends are attached to the central pad. A semiconductor chip is mounted on the first pad surface and electrically connected to the first segment ends. Encapsulation material, preferably molding compound, surrounds the chip, electrical connections, first segment ends, and first handle ends, and further fills the gap, but leaves the second spreader surface, second segment ends, and second handle ends exposed.

Another embodiment of the invention is a method for fabricating a semiconductor device as described above. After the process step, which fills the gap between the heat spreader and the first leadframe segment ends with adhesive encapsulation material, the leadframe members including the inserted portions of the spreader handles are trimmed and removed, and the second segment ends can be formed for attachment to external parts.

It is a technical advantage of the invention that it offers low-cost design and structure options for the projections of the leadframe clamps. In one embodiment, the projections are flanges formed from the planar leadframe sheet at approximately right angles and configured to grasp one of the spreader handles. In another embodiment, the flanges may comprise protruding dimples facing the inserted spreader handle so that the dimples lock the inserted handle in place.

It is another technical advantage that the innovation of the invention is accomplished using the installed equipment base for leadframe manufacture so that no investment in new manufacturing machines is needed.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a bottom view of a semiconductor device leadframe according to an embodiment of the invention, exhibiting a plurality of members operable as mechanical couplers configured to grip inserted objects.

FIG. 2 is a magnified bottom view of one of the leadframe members illustrated in FIG. 1.

FIG. 3 is a bottom view of an apparatus according to another embodiment of the invention, showing a heat spreader with handles coupled with the members of the leadframe in FIG. 1.

FIG. 4 is the top view of the apparatus shown in FIG. 3.

FIG. 5 is a magnified top view of a portion of the apparatus shown in FIG. 4, illustrating a handle of the heat spreader inserted into the clamp-shaped end of a leadframe member.

FIG. 6 is a detailed top view of the leadframe member in FIG. 5, illustrating the flange-shape projections of the clamp, with the spreader handle inserted, and the bend of the member.

FIG. 7 is a top view of the encapsulated semiconductor device integral with the leadframe and heat spreader according to embodiments of the invention.

FIG. 8 is a top view of the semiconductor device of FIG. 7 after trimming and forming the leadframe and heat spreader.

FIG. 9 illustrates the bottom view of a leadframe member portion according to another embodiment of the invention.

FIG. 10 is a top view of a leadframe portion, depicting a member according to another embodiment of the invention.

### DETAILED DESCRIPTION OF THE PREFERRED EMBODIMENTS

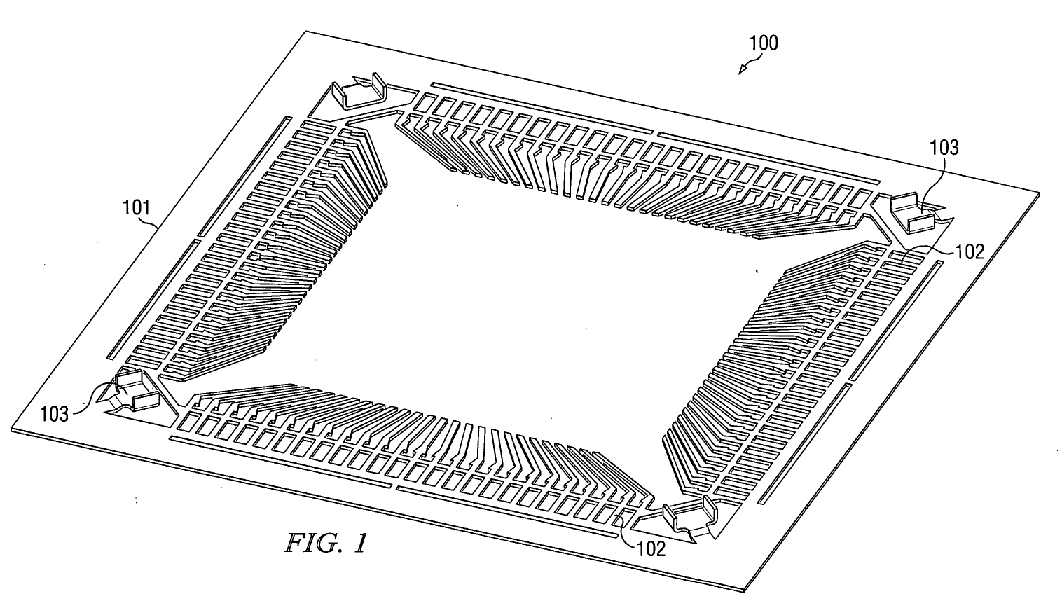

FIG. 1 depicts the bottom view of a semiconductor device leadframe (in this example, for a 100-pin device), generally designated 100, in order to illustrate an embodiment of the invention. Leadframe 100 is made from a planar metal sheet and has a frame 101, which holds together the plurality of segments 102 operable as electrical connectors. Since frame 101 and segments 102 are made from the planar sheet of metal, they are laid out in one plane. Leadframe 101 is preferably made of copper or a copper alloy in the preferred thickness range from 100 to 300 μm; thinner sheets are possible. The ductility in this thickness range provides the 5 to 15% elongation that facilitates the segment bending and forming operation. The leadframe is stamped or etched from the starting metal sheet.

Alternative sheet metals include brass, aluminum, iron-nickel alloys (such as “Alloy 42”), and covar. Frequently, the sheet metal is fully covered with a plated layer; as an example, the copper base metal may be plated with a nickel layer.

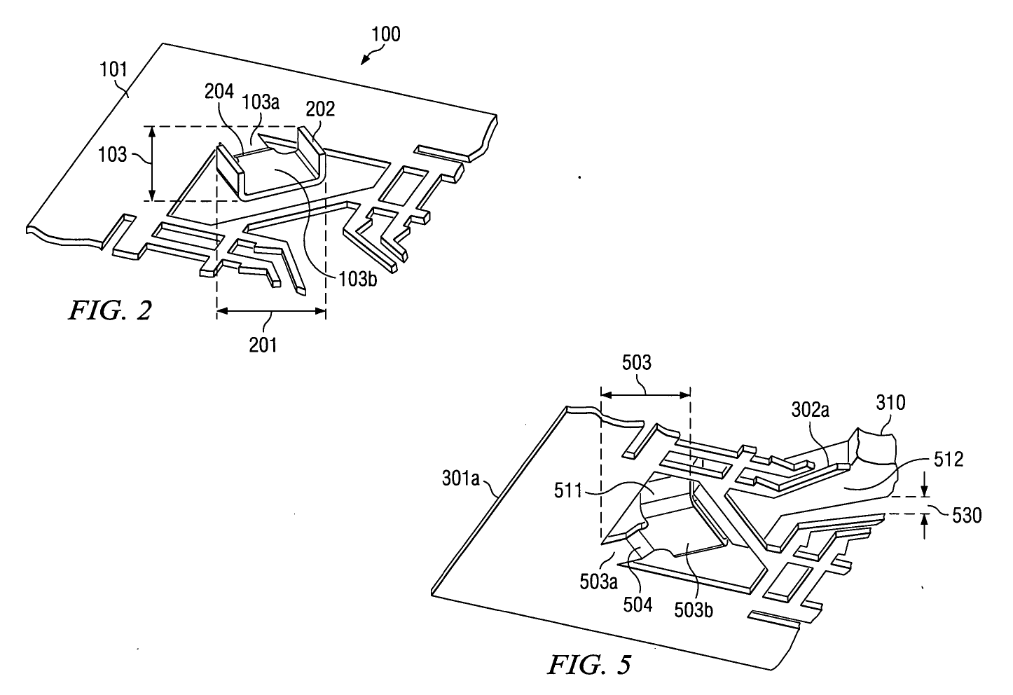

FIG. 1 further shows leadframe 101 having a plurality of members 103, which are operable as mechanical couplers configured to grip inserted objects, and which are further non-coplanar. FIG. 2 is a magnified bottom view of one of the leadframe members 103 in order to illustrate in detail the non-coplanarity and other features. Member 103 has a first end 103a, which is attached to frame 101, and a second end 103b, which is formed as a clamp 201. In the embodiment shown in FIG. 2, clamp 201 has two projections 202 extending from the planar sheet. These projections are operable to secure a suitably formed object, when it is inserted into the clamp. The non-coplanarity of member 103 is provided by a bend 204 in member 103, which is preferably located near the attachment of member 103 to frame 101.

As FIG. 2 indicates, projections 202 may be flanges formed from the original planar sheet of leadframe metal at approximately right angles. They are thus configured to grasp an inserted suitable object and hold it steady so that it cannot move laterally or rotate.

Other embodiments of projections 202 are illustrated in FIGS. 9 and 10. FIG. 9 is the bottom view of a leadframe member 903, which has a first end 903a attached to leadframe 901, and a second end 903b formed as a clamp 910. Furthermore, member 903 has a bend 904 near the first end 903a, which renders second end 903b non-coplanar with regard to leadframe 901. Clamp 910 has two flanges 911 extending from the planar portion of member end 903b. As FIG. 9 shows, each flange 911 has a protruding dimple 912, which faces the inside of the clamp 910. Dimples 912 are operable to lock in place a suitable object inserted into clamp 910.

FIG. 10 shows a top view of a portion 1001 of the leadframe; the depicted member 1003 has a first end 1003a attached to leadframe 1001, and a second end 1003b formed as a clamp 1010. Furthermore, member 1003 has a bend 1004 near the first and 1003a, which renders second end 1003b non-coplanar with regard to leadframe 1001. Clamp 1010 has two flanges 1011 extending from the planar portion of member end 1003b. As FIG. 10 shows, flanges 1011 are formed at an angle 1012 of slightly more than 90° relative to the plane of the starting leadframe sheet. This obtuse angle allows flanges 1011 to exert pressure on an inserted object and provides thus a strong grip of clamp 1010 on this object.

It should be stressed that the function of the members to operate as couplers configured to grip inserted objects can be accomplished by alternative embodiments. As an example, the member may include a dimple, which couples with a groove or hole provided in the inserted object. Or the member may be formed as a hook, which couples with another hook provided in the inserted object. Or the coupling may be provided by means of solder between the member and the object.

It should further be pointed out that bend 204 and thus at least a portion of the non-coplanarity of member 103 may be absent in those embodiments, which provide an electrical insulation layer on the inserted object to keep it electrically isolated from segments 102.

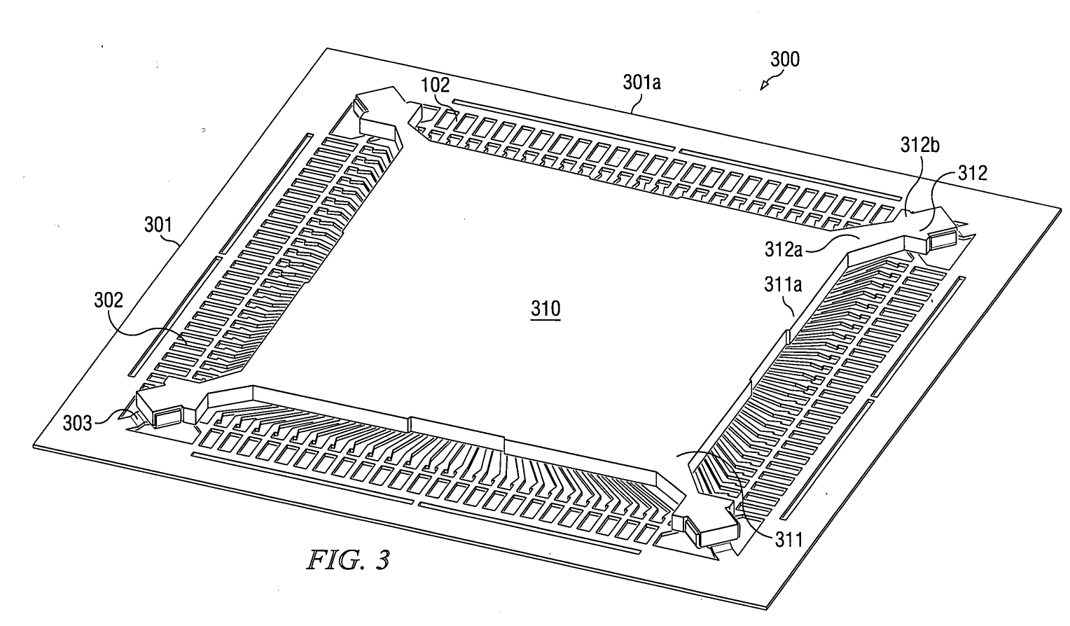

FIG. 3 is a bottom view of another embodiment of the invention. Illustrated in FIG. 3 is an apparatus generally designated 300, which comprises a leadframe 301 coupled with a metallic heat spreader 310. Apparatus 300 is intended for a 100-pin semiconductor device. Leadframe 301 is made from a planar metal sheet; it includes a frame 301a and a plurality of segments 302 operable as electrical connectors. Segments 302 are attached to frame 301a. The sheet of leadframe 301 is preferably 100 to 300 μm thick and made of copper, a copper alloy, or copper plated with nickel; alternatively, leadframe 301 is made of aluminum, an iron-nickel alloy, or cover. The leadframe further has a plurality of non-coplanar members 303 operable as mechanical couplers configured to grip inserted objects.

The metallic heat spreader 310 has a central pad 311 with perimeter 311a, suitable for mounting a heat-generating object (actually on the pad surface opposite to the surface shown in FIG. 3). The spreader further has a plurality of handles 312 in locations to match the locations of the leadframe members 303, respectively. The spreader 310 is preferably made of copper or a copper alloy, and has a thickness range from approximately 0.2 to 2.5 mm, preferably about 0.5 mm. Each handle 312 has a first end 312a, which is attached to the central pad 311 of the heat spreader, and a second end 312b, which matches the location of the respective leadframe member (clamp). As FIG. 3 shows, each handle 312 of the heat spreader is coupled with its respective leadframe member 303 (consequently, the central pad 311 of spreader 310 obscures portions of segments 302 in FIG. 3).

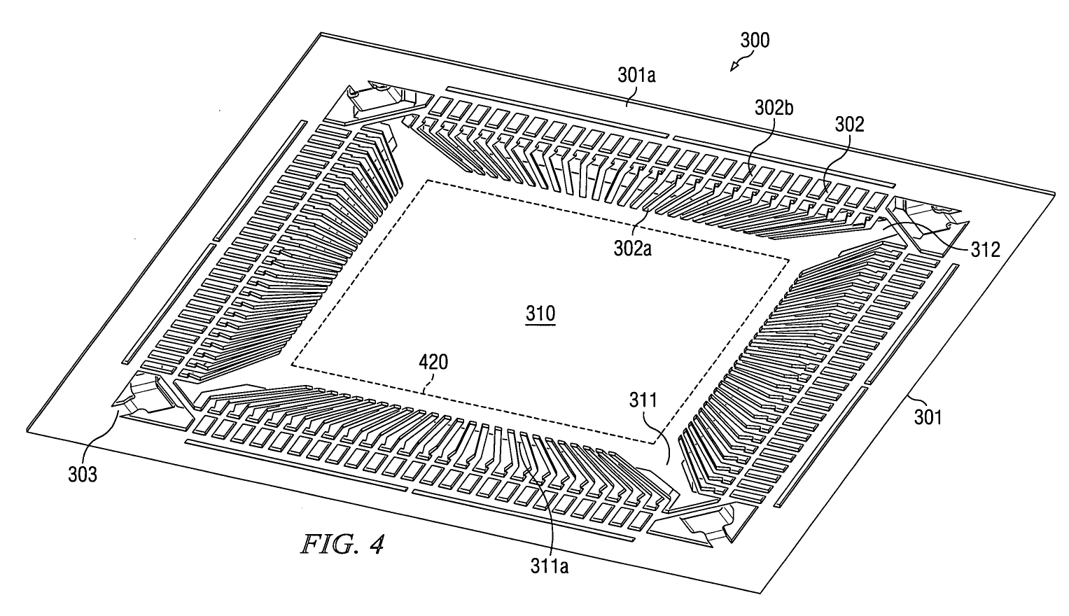

FIG. 4 is a top view of apparatus 300. Leadframe 301 includes frame 301a and the plurality of leadframe segments 302. Each segment 302 has a first end 302a, operable to be connected to a chip input/output pad, and a second end 302b, connected to frame 301a. The segments 302 are in the plane defined by the starting sheet of the leadframe. Leadframe 301 further has a plurality of non-coplanar members 303 operable as mechanical couplers configured to grip inserted objects.

Further shown in the apparatus of FIG. 4 is heat spreader 310 with its central pad 311, outlined by lines 311a. The semiconductor chip to be mounted onto the spreader surface depicted in FIG. 4 will fit into the spreader area left over by the plurality of segments 302 reaching slightly over the spreader outline 311a, an example of a suitable chip size is outlined in FIG. 4 by dashed lines 420. It is evident that a large variety of ship sizes can be accommodated in the available spreader area.

Spreader 310 further has a plurality of handles 312 in locations to match the locations of the leadframe members 303, respectively. Each handle 312 is coupled with its respective member 303.

FIG. 5 depicts the magnified top view of a portion of the apparatus 300 shown in FIG. 4 in order to illustrate in more detail the insertion of the heat spreader handle into the clamp-shaped end of a leadframe member. Member 503 has its first end 503a attached to frame 301a and its second end 503b formed as a clamp. In the apparatus shown in FIG. 5, the clamp has two projections 511 extending from the planar sheet. These projections are operable to grip the heat spreader handle 512, when it is inserted into the clamp. Member 503 is non-coplanar with regard to the leadframe sheet due to a bend 504 in member 503. Bend 504 is preferably located near the attachment of first member end 503a to frame 301a. The extent of bend 504 within the ductility of the leadframe material depends on the thickness of heat spreader handle 512.

As a consequence of bend 504, heat spreader handle 512 and heat spreader 310 are, after insertion of handle 512 into the member clamp, in a plane, which is spaced from the leadframe plane. A gap 530 is thus provided between the spreader 310 and the first segment ends 503a of the leadframe.

Alternatively, leadframe bend 504, gap 530 between first segment ends 503a of the leadframe and heat spreader 310, and the spacing of the plane of heat spreader 310 from the leadframe plane may be absent in those embodiments, which provide an electrical insulation attached to at least portion of spreader 310. Suitable insulation on the spreader may be provided by polyimide- or epoxy-based layers, sprayed-on polymeric materials, and related means.

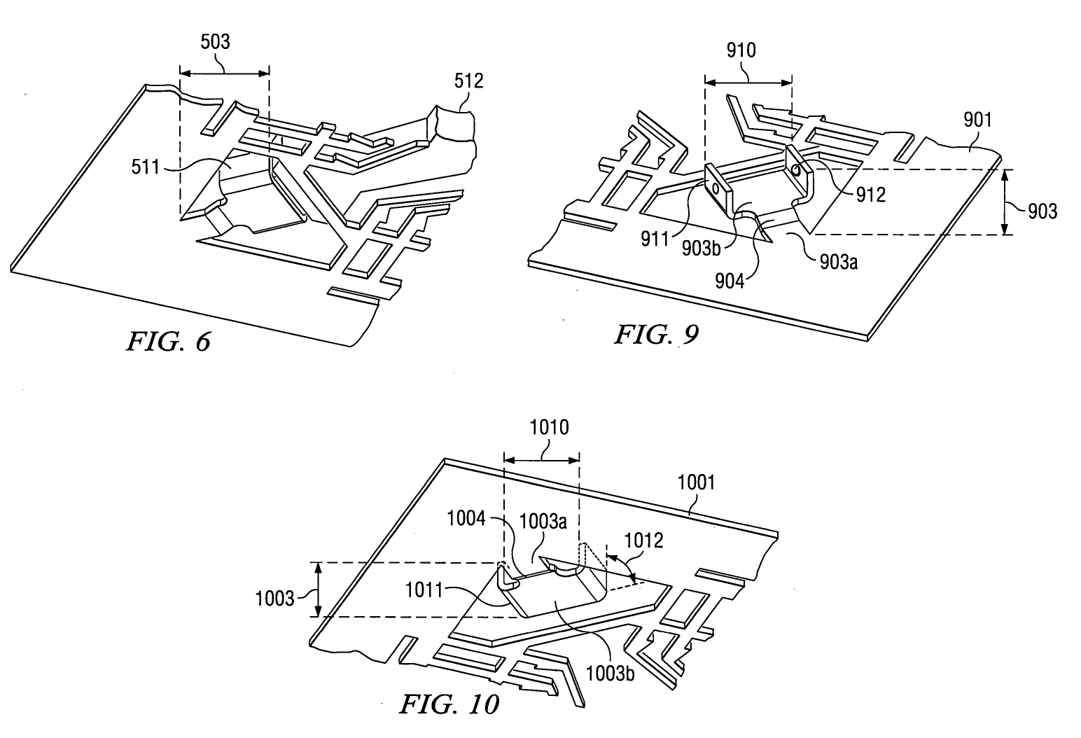

FIG. 6 shows a still higher magnification of the same leadframe member 503 illustrated in FIG. 5. FIG. 6 depicts the clamp projections 511 as flanges formed from the original leadframe sheet so that they are at approximately right angles to the central portion of the clamp and configured to grasp the suitable formed spreader handle 512.

Another embodiment of the invention is a method for fabricating a semiconductor device, which comprises the following steps: A leadframe is provided, which is made from a planar metal sheet. This leadframe includes a plurality of segments, which have first and second ends; it further includes a plurality of non-coplanar members, which have first and second ends, whereby the first member ends are attached to the leadframe and the second member ends have clamps operable as mechanical couplers configured to grip inserted objects. In addition, each second member end includes a bend so that the clamps are in a plane spaced from the metal sheet plane by a gap.

Furthermore, a metallic heat spreader is provided, which has first and second surfaces, a central pad suitable for mounting a heat-generating object on the first surface, and a plurality of handles, which have first and second ends. The first handle ends are attached to the central pad, and the handles are in locations to match the locations of the leadframe members, respectively.

In the next process step, the spreader handles are inserted into the clamps, respectively; because of the bend in the second member end, the spreader is now spaced from the metal sheet plane by the gap mentioned above.

Next, a semiconductor chip, which is provided, is mounted on the first surface of the spreader pad and then electrically connected with the first leadframe segment ends. The chip, the electrical connections, the first segment ends, and the first handle ends are then encapsulated with insulating material, preferably with a molding compound; in the same process step, the gap is filled. The encapsulation step, however, leaves the second spreader surface, the second segment ends, and second handle ends exposed.

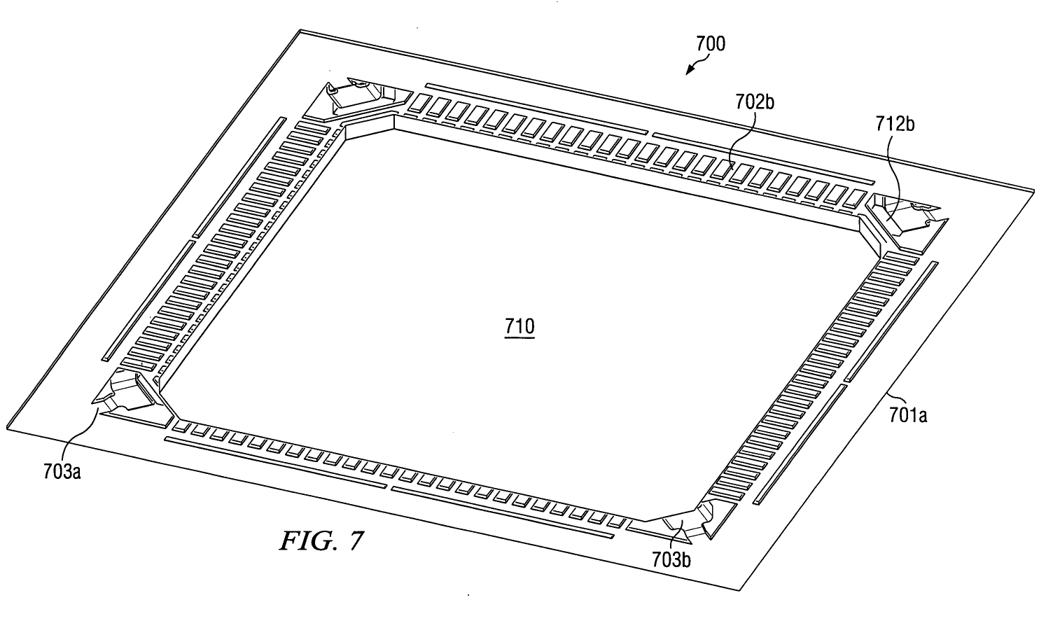

At this point in the process flow, the product looks like the example illustrated in FIG. 7, a 100-pin device, generally designated 700, as an example of a device embodiment of the invention. 710 denotes the encapsulation material, 701a the exposed frame of the leadframe, 702b the second segment ends, 703a the first member ends, 703b the second member ends with the clamps, and 712b the second handle ends of the heat spreader. Since FIG. 7 is a top view, the exposed second spreader surface is not shown.

In the next process step, the leadframe is trimmed so that the members including the inserted portions of the spreader handles are removed. Finally the second segment ends are formed to obtain the shape needed for connection to external parts.

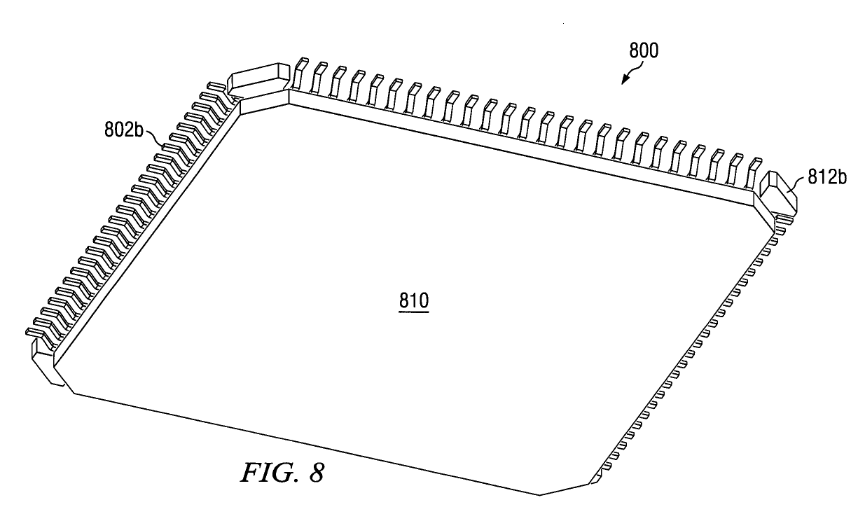

At this point in the process flow, the product looks like the example illustrated in FIG. 8, a finished 100-pin device, generally designated 800, as an example of a device embodiment of the invention. 810 denotes the encapsulation material, 802b the formed second segment ends of the leadframe, and 812b the portion of the second handle ends of the heat spreader, which has remained after the forming process. Since FIG. 8 is a top view, the exposed second spreader surface is not shown.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the invention covers integrated circuits made in substrates of silicon, silicon germanium, gallium arsenide, or any other semiconductor material used in integrated circuit manufacture.

As another example, the invention covers generally a heat-generating semiconductor unit. This concept thus includes single-chip as well as multi-chip devices. Further, the concept includes devices employing wire-bonded assembly as well as flip-chip assembly.

It is therefore intended that the appended claims encompass any such modifications or embodiments.

We claim:

1. A leadframe made from a planar metal sheet comprising:
a plurality of segments operable as electrical connectors; and
a plurality of non-coplanar members operable as mechanical couplers configured to secure inserted objects.

2. The leadframe according to claim 1 wherein said non-coplanarity is provided by a bend in said members near their attachment to said leadframe.

3. An apparatus comprising:
a leadframe comprising a planar metal sheet, said leadframe including a plurality of segments operable as electrical connectors and a plurality of non-coplanar members operable as mechanical couplers configured to secure inserted objects;
a metallic heat spreader having a central pad suitable for mounting a heat-generating object, and a plurality of handles in locations matching said coupler members.

4. The apparatus according to claim 3 wherein each of said members has first and second ends, said first end attached to said leadframe and said second end formed as a clamp having projections from said planar sheet, operable to grip one of said handles, when it is inserted into said clamp.

5. The apparatus according to claim 4 wherein each member further comprises a bend in said first member end so that said heat spreader, after insertion of its handles into said clamps, is in a plane, which is spaced from said leadframe plane, whereby a gap is provided between said spreader and said first segment ends.

6. The apparatus according to claim 4 wherein said projections are flanges formed from said planar sheet at approximately right angles and configured to grasp one of said handles.

7. The apparatus according to claim 6 wherein said flanges further comprise protruding dimples facing said inserted handle, said dimples operable to lock in place said inserted handle.

8. A semiconductor device comprising:
a leadframe including a plurality of segments having first and second ends, said first ends in a first plane;
a metallic heat spreader in a second plane, said second plane spaced from said first plane by a gap, said spreader having first and second surfaces, a central pad suitable for mounting a heat-generating object on said first surface, and a plurality of handles having first and second ends, said first handle ends attached to said central pad;
a semiconductor chip mounted on said first surface of said spreader pad and electrically connected to said first segment ends; and
encapsulation material covering said chip, electrical connections, first segment ends, and first handle ends, further filling said gap, and uncovering said second spreader surface, second segment ends, and second handle ends exposed.

9. The device according to claim 8 wherein said second segment ends are formed so that they are operable for attachment to external parts.

10. A method for fabricating a semiconductor device comprising the steps of:
providing a leadframe made from a planar metal sheet, said leadframe including a plurality of segments having first and second ends, and a plurality of non-coplanar members having first and second ends, said first member ends attached to said leadframe and said second member ends having couplers operable to secure inserted objects, said second member ends further including a bend so that said clamps are in a plane spaced from said metal sheet plane by a gap;
providing a metallic heat spreader having first and second surfaces, a central pad suitable for mounting a heat-generating object on said first surface, and a plurality of handles having first and second ends, said first handle ends attached to said central pad, said handles in locations to match said members;
inserting said spreader handles into said couplers, whereby said spreader is spaced from said metal sheet plane by said gap;
providing a semiconductor chip and mounting said chip on said first pad surface;
electrically connecting said chip with said first segment ends; and
encapsulating said chip, electrical connections, first segment ends, and first handle ends with insulating material and concurrently filling said gap, while leaving said second spreader surface, second segment ends, and second handle ends uncovered.

11. The method according to claim 10 further comprising the steps of:
trimming said leadframe so that said members including the inserted portions of said spreader handles are removed; and forming said second segment ends.
